(19) United States
(12) Patent Application Publication
(10) Pub. No.: US 2010/0176517 A1
(43) Pub. Date: Jul. 15, 2010

(54) Electronic device

(75) Inventors: Yuichi Miyagawa, Kanagawa (JP); Jun Tsukano, Kanagawa (JP); Kenji Furuya, Kanagawa (JP); Takamitsu Noda, Kanagawa (JP); Hiroyasu Miyamoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/654,834

(22) Filed: Jan. 6, 2010

(30) Foreign Application Priority Data
Jan. 13, 2009 (JP) 5100/2009

(51) Int. Cl. H01L 23/28

(52) U.S. Cl. 257/788; 257/787; 257/E23.116

(57) ABSTRACT

Differences in contraction forces of a sealing resin can be alleviated and strain on a package can be reduced even when electronic components are unevenly positioned on a substrate. An electronic device (100) includes a substrate 102, electronic components (104, 108) mounted on one face of the substrate 102, and a sealing resin 118 formed on the one face of the substrate 102 and which seals the electronic components. The sealing resin 118 includes a first resin region 120 made up of a first resin composition and a second resin region 122 made up of a second resin composition, and is formed so as to have, as seen in planar view, a region in which only the first resin region 120 exists and a region in which only the second resin region 122 exists.

### BACKGROUND OF THE INVENTION

1. Field of the Invention

The present invention relates to an electronic device.

2. Description of the Related Art

There are known techniques for forming a packet by mounting an electronic component such as a semiconductor chip onto a substrate and subsequently sealing the semiconductor chip with a sealing resin. Conventionally, sealing is performed using a single resin composition. However, when a bonding wire exists, it is necessary to prevent the wire from being swept in the resin and therefore toppled when sealing the semiconductor chip with a sealing resin.

It is also necessary to suppress warpage behavior of a sealed package. When using a single resin composition, it is difficult to optimize resin material so as to simultaneously satisfy such demands. Therefore, obtaining optimal characteristics requires that a large number of resin materials be prepared and/or developed, resulting in high cost and low productivity.

Japanese Patent Laid-Open No. 08-162573 discloses a semiconductor device in which a semiconductor element is mounted via an adhesive layer on a substrate on which a circuit is formed, whereby the semiconductor element is sealed by a resin hardened body layer having a two-layer structure made up of a resin hardened body inner layer and a resin hardened body outer layer. In this case, the filler content of the resin hardened body inner layer is set lower than the filler content of the resin hardened body outer layer. Accordingly, the disclosure purports that occurrences of wire sweep can be suppressed and a semiconductor device with a lower risk of warpage occurrence can be provided.

However, in cases where a plurality of electronic components such as a semiconductor chip and a passive component are mounted on a substrate or where electronic components are not positioned at the center of a substrate, there is a problem in that the positional balance between the sealing resin and the electronic components differs from location to location, causing differences in the contraction force (internal force) of the sealing resin and creating a strain in the package. The technique disclosed in Japanese Patent Laid-Open No. 08-162573 does not provide control that takes such positional balances between the sealing resin and electronic components into consideration.

### SUMMARY

The present invention provides an electronic device including a substrate, an electronic component mounted on one face of the substrate, and a sealing resin formed on the one face of the substrate and which seals the electronic component, wherein the sealing resin includes a first resin region made up of a first resin composition and a second resin region made up of a second resin composition, the sealing resin formed so as to have, as seen in planar view, a region in which only the first resin region exists and a region in which only the second resin region exists.

Accordingly, for example, even when the positional balance between the sealing resin and electronic components such as a semiconductor chip and passive components differs from location to location, by using a plurality of resin compositions to provide a region in which, as seen in planar view, the electronic components are positioned so as not to overlap each other, and controlling the positional patterns and configurations of a first resin region and a second resin region, balance can be corrected to reduce the strain on the package and thus reduce warpage.

Moreover, arbitrary combinations of the components described above, as well as mutual conversions of the expressions of the present invention among methods, devices, and the like are also valid as aspects of the present invention.

According to the present invention, even when an electronic component is unevenly positioned on a substrate, differences in contraction forces of a sealing resin can be alleviated and strain on a package can be reduced.

### BRIEF DESCRIPTION OF THE DRAWINGS

FIG. 1 is a cross-sectional view illustrating an example of a configuration of a semiconductor device according to an embodiment of the present invention;

FIGS. 2A and 2B are plan views illustrating an example of a configuration of a semiconductor device according to an embodiment of the present invention;

FIG. 3 is a cross-sectional view illustrating another example of a configuration of a semiconductor device according to an embodiment of the present invention;

FIG. 4 is a plan view illustrating another example of a configuration of a semiconductor device according to an embodiment of the present invention;

FIG. 5 is a plan view illustrating another example of a configuration of a semiconductor device according to an embodiment of the present invention;

FIG. 6 is a plan view illustrating another example of a configuration of a semiconductor device according to an embodiment of the present invention;

FIGS. 7A and 7B are cross-sectional views illustrating a procedure for manufacturing a semiconductor device using a transfer-molding die according to an embodiment of the present invention; and

FIGS. 8A and 8B are cross-sectional views illustrating a procedure for manufacturing a semiconductor device using a transfer-molding die according to an embodiment of the present invention.

### DETAILED DESCRIPTION OF THE PREFERRED EMBODIMENT

Hereinafter, an embodiment of the present invention will be described with reference to the drawings. Throughout all of the drawings, like components will be denoted by like reference numerals and descriptions thereof will be omitted where appropriate.

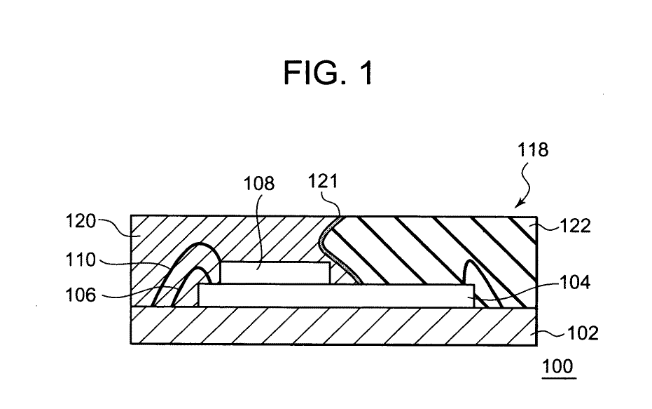

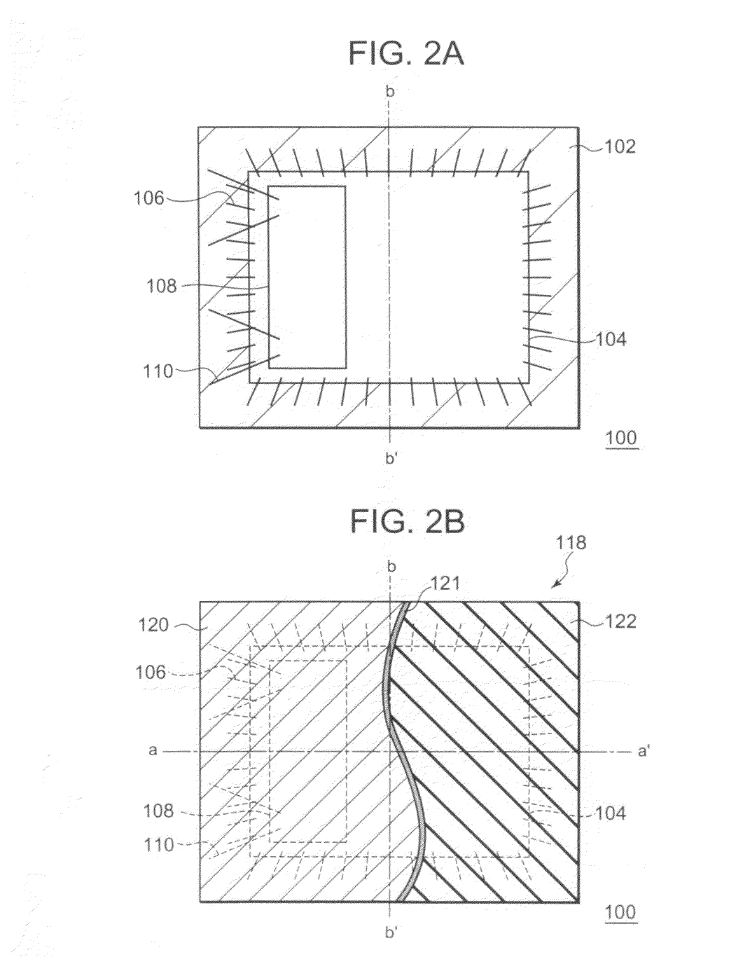

FIG. 1 is a cross-sectional view illustrating an example of a configuration of a semiconductor device according to the present embodiment. FIG. 2 is a plan view illustrating an example of the configuration of a semiconductor device according to the present embodiment. FIG. 1 corresponds to an a-a′ cross-sectional view of FIG. 2B.

An semiconductor device 100 (electronic device) includes a substrate 102, a semiconductor chip 104 (electronic component) mounted on one face of the substrate 102, a bonding wire 106 that electrically connects the semiconductor chip 104 and the substrate 102, a semiconductor chip 108 (electronic component) positioned on top of the semiconductor chip 104, a bonding wire 110 that electrically connects the semiconductor chip 108 and the substrate 102, and a sealing resin 118. Moreover, the semiconductor chip 104, the bonding wire 106, the semiconductor chip 108, and the bonding wire 110 are embedded in the sealing resin 118. In the present embodiment, the substrate 102 can take the form of a multilayer wiring substrate in which a plurality of wiring layers are connected to each other.

FIG. 2A is a plan view illustrating a state before the semiconductor chip 104, the bonding wire 106, the semiconductor chip 108, and the bonding wire 110 are sealed by the sealing resin 118. In the present embodiment, the semiconductor chip 104 and the semiconductor chip 108 are asymmetrically-positioned with respect to at least one center line passing through the center of the substrate 102. Specifically, the semiconductor chip 104 is symmetrically-positioned with respect to line b-b′ passing through the center of the substrate 102. On the other hand, the semiconductor chip 108 is asymmetrically-positioned with respect to the line b-b′. As a result, the semiconductor chip 104 and the semiconductor chip 108 are asymmetrically-positioned with respect to the line b-b′.

FIG. 2B is a plan view illustrating a state after the semiconductor chip 104, the bonding wire 106, the semiconductor chip 108, and the bonding wire 110 are sealed by the sealing resin 118. In FIG. 2B, the semiconductor chip 104, the bonding wire 106, the semiconductor chip 108, and the bonding wire 110 are depicted in dashed lines so that their positional relationship is better understood.

In the present embodiment, the sealing resin 118 includes a first resin region 120 made up of a first resin composition and a second resin region 122 made up of a second resin composition. In addition, the sealing resin 118 is formed so as to include, as seen in planar view, a region in which only the first resin region 120 exists and a region in which only the second resin region 122 exists. Furthermore, the sealing resin 118 includes a mixed layer 121 formed between the first resin region 120 and the second resin region 122 and which contains a mixture of the first resin composition and the second resin composition. The interface between the first resin region 120 and the mixed layer 121 and the interface between the second resin region 122 and the mixed layer 121 respectively have undulations.

In the example illustrated in FIG. 1, with the line b-b′ as a borderline, the first resin region 120 is formed on a left-side region as shown in the diagram in which the semiconductor chip 108 is positioned. On the other hand, the second resin region 122 is formed on a right-side region as shown in the diagram in which the semiconductor chip 108 is not positioned. In addition, the mixed layer 121 is formed over the entire region between the first resin region 120 and the second resin region 122. In other words, the semiconductor chip 108 and the bonding wire 110 are embedded in the first resin region 120. In addition, as far as the semiconductor chip 104 and the bonding wire 106 are concerned, half is embedded in the first resin region 120 and the remaining half is embedded in the second resin region 122.

The first resin composition that makes up the first resin region 120 and the second resin composition that makes up the second resin region 122 can respectively include, as raw materials, a base resin, a hardening agent, and a filler. In addition, the first resin composition and the second resin composition can further include, as raw materials, a plasticizer, a hardening accelerator, a latent catalyst, a mold release agent, silicone oil, a stress reducer, a colorant, and the like. For example, a silica or alumina filler can be used as the filler.

For example, the first resin composition and the second resin composition can be arranged so as to differ from each other in fluidity when heated during sealing prior to hardening. In addition, the first resin composition and the second resin composition may be arranged so as to have, for example, different hardening/contraction characteristics. Furthermore, the first resin composition and the second resin composition may be arranged so as to have, for example, different glass-transition temperatures (Tg). The difference in the glass-transition temperatures of the first resin composition and the second resin composition can be set to, for example, 5 degrees Celsius or more.

In addition, the first resin composition and the second resin composition may be arranged so as to have, for example, different filler contents (percentage by weight) with respect to the entire resin composition. By reducing the filler content (percentage by weight), the fluidity of a resin composition can be increased. The difference in filler contents (percentage by weight) with respect to the entire resin composition between the first resin composition and the second resin composition can be set to, for example, 1 percent by weight or higher.

In addition, the first resin composition and the second resin composition may be arranged so as to respectively contain, for example, fillers with different average particle diameters. By increasing the average particle diameter of a filler, the fluidity of a resin composition can be increased. The difference in the average particle diameters of fillers respectively contained in the first resin composition and the second resin composition can be set to, for example, 5 μm or greater.

Furthermore, the first resin composition and the second resin composition may be arranged so as to have, for example, different raw material types or ratios. The first resin composition and the second resin composition may be arranged so as to have, for example, different base resins or hardening agents.

In the present embodiment, for example, a region in which the first resin region 120 is formed has a lower average resin amount per unit volume as compared to a region in which the second resin region 122 is formed. In such a case, through optimization involving differentiating the filler amount and the like of the first resin composition that makes up the first resin region 120 from that of the second resin composition that makes up the second resin region 122, warpage or strain of the semiconductor device 100 can be reduced.

Moreover, a high-fluidity resin composition can be used for a region containing a large number of bonding wires. For instance, in the current example, the first resin composition that makes up the first resin region 120 can be arranged to have high fluidity. Consequently, bonding wires can be prevented from being swept away and toppled in the resin. In addition, a low-fluidity resin composition can be used for a region containing a small number of bonding wires. This is because, generally, the use of a low-fluidity resin composition enables a reduction in contraction of hardened resin and lowers the occurrence of warpage.

In the present embodiment, warpage behavior can be controlled by changing the component ratio of the first resin composition and the second resin composition. Therefore, a highly-reliable package structure with low warpage during sealing and low package warpage can be obtained without having to prepare a large number of resin compositions. In this case, for example, the component ratio of the first resin composition and the second resin composition can be set to first resin composition:second resin composition=equal to or greater than 99:1 and equal to or lower than 1:99, and preferably to equal to or greater than 90:10 and equal to or lower than 10:90. Consequently, the warpage amount of the semiconductor device 100 can be controlled.

Furthermore, in the present embodiment, by having the mixed layer 121 exist between the first resin region 120 and the second resin region 122, a favorable adhesion can be obtained between the first resin region 120 and the second resin region 122 and separation between the two regions can be prevented. In addition, in the present embodiment, since the interface between the first resin region 120 and the mixed layer 121 and the interface between the second resin region 122 and the mixed layer 121 respectively have undulations and are not smooth, the adhesion between the first resin region 120 and the mixed layer 121 and between the second resin region 122 and the mixed layer 121 can be further increased. In this case, “having undulations” refers to a configuration in which, as seen in sectional view of an interface, a plurality of depressions and protrusions is formed.

While the film thickness (mold thickness) of the sealing resin 118 is not particularly limited, for example, the film thickness can be set to around 0.10 mm or more and 1.20 mm or less. Accordingly, an optimal package structure can be obtained.

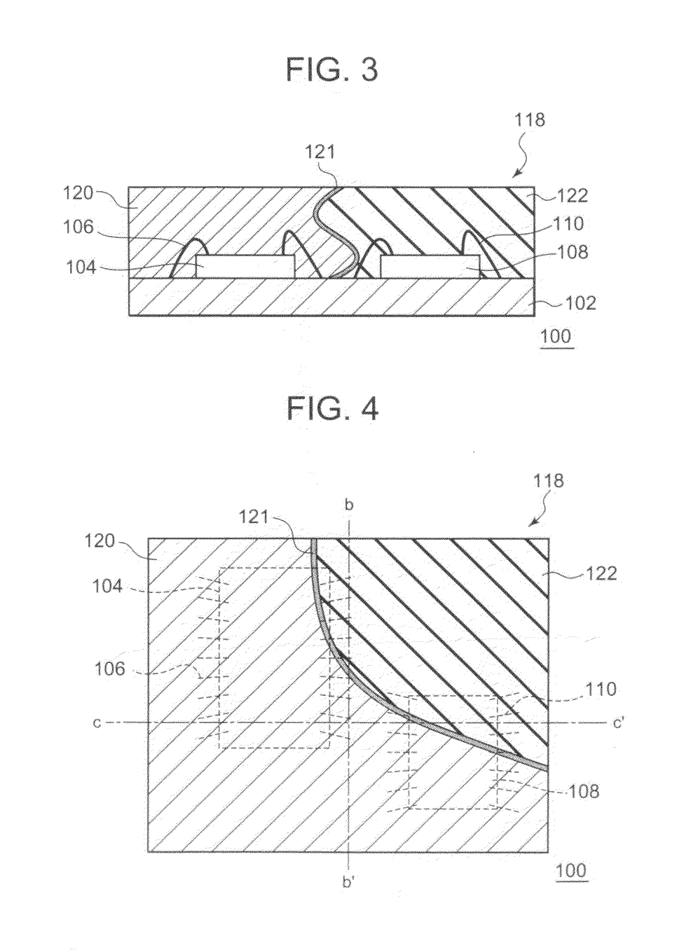

FIG. 3 is a cross-sectional view illustrating another example of a configuration of the semiconductor device 100 according to the present embodiment. FIG. 4 is a plan view illustrating another example of a configuration of the semiconductor device 100 according to the present embodiment. FIG. 3 corresponds to a c-c′ cross-sectional view of FIG. 4. In FIG. 4, the semiconductor chip 104, the bonding wire 106, the semiconductor chip 108, and the bonding wire 110 are depicted in dashed lines so that their positional relationship is better understood.

In the present example, the semiconductor chip 104 and the semiconductor chip 108 are juxtaposed on the substrate 102. In addition, as illustrated in FIG. 4, also in the present example, the semiconductor chip 104 and the semiconductor chip 108 are asymmetrically-positioned with respect to at least one center line passing through the center of the substrate 102. Specifically, the semiconductor chip 104 and the semiconductor chip 108 are asymmetrically-positioned with respect to line b-b′ passing through the center of the substrate 102.

Even in such a configuration, for example, the first resin region 120 is formed in a primary region in which the semiconductor chip 104 and the semiconductor chip 108 are positioned, and a second resin region 122 is formed in another region. In addition, the mixed layer 121 is formed over the entire region between the first resin region 120 and the second resin region 122.

In the present example, for instance, the region in which the first resin region 120 is formed has a lower average resin amount per unit volume as compared to the region in which the second resin region 122 is formed. In such a case, through optimization involving differentiating the filler amount and the like of the first resin composition that makes up the first resin region 120 from that of the second resin composition that makes up the second resin region 122, warpage or strain of the semiconductor device 100 can be reduced. Moreover, while a configuration is shown in which the second resin region 122 partially overlaps the semiconductor chip 104 and the semiconductor chip 108, a configuration is also possible in which the second resin region 122 is provided at a region other than that in which the semiconductor chip 104 and the semiconductor chip 108 are positioned.

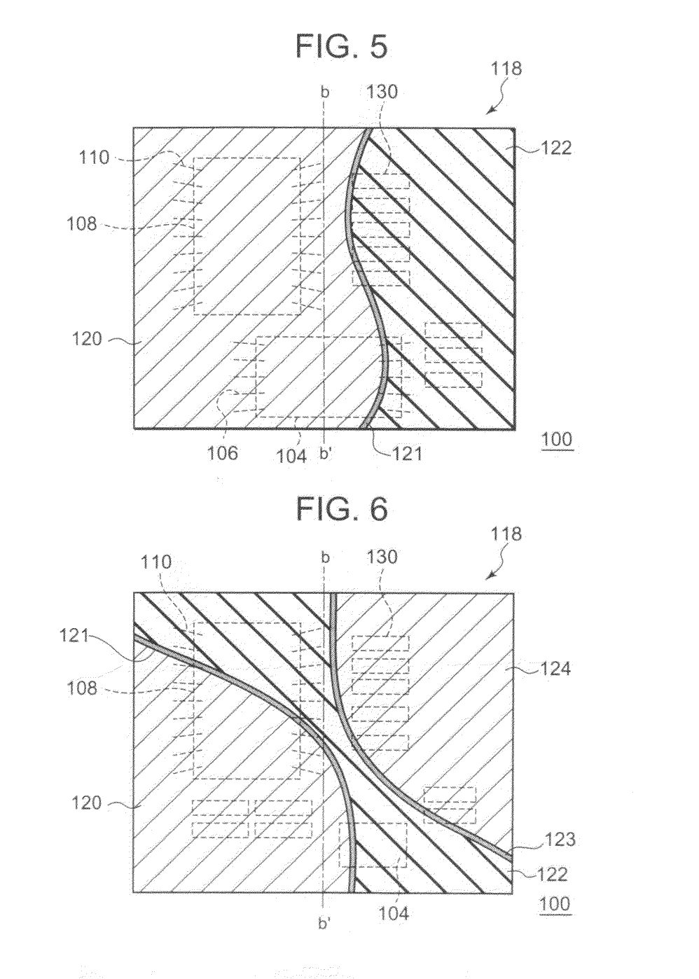

FIG. 5 is a plan view illustrating yet another example of a configuration of the semiconductor device 100 according to the present embodiment. In this configuration, the semiconductor device 100 includes a plurality of passive components 130 in addition to the semiconductor chip 104, the bonding wire 106, the semiconductor chip 108, and the bonding wire 110. In FIG. 5, the semiconductor chip 104, the bonding wire 106, the semiconductor chip 108, the bonding wire 110, and the passive components 130 are depicted in dashed lines so that their positional relationship is better understood.

In addition, also in the present example, the semiconductor chip 104, the semiconductor chip 108, and the plurality of passive components 130 are asymmetrically-positioned with respect to at least line b-b′ that is one center line passing through the center of the substrate 102.

Even in such a configuration, for example, the first resin region 120 is formed in a region in which the semiconductor chip 104 and the semiconductor chip 108 are positioned, while the second resin region 122 is formed in a region in which the passive components 130 are formed. In addition, the mixed layer 121 is formed over the entire region between the first resin region 120 and the second resin region 122.

In this case, a large number of bonding wires exist in the first resin region 120. Therefore, a high-fluidity resin composition can be used as the resin composition that makes up the first resin region 120. Consequently, bonding wires can be prevented from being swept away and toppled in the resin. On the other hand, a low-fluidity resin composition can be used as the resin composition that makes up the second resin region 122 that does not include a large number of bonding wires. Accordingly, the warpage behavior of the semiconductor device 100 can be controlled while preventing the bonding wire 106 from being swept away.

FIG. 6 is a plan view illustrating still another example of a configuration of the semiconductor device 100 according to the present embodiment. In this configuration, the semiconductor device 100 includes the semiconductor chip 104, the semiconductor chip 108, the bonding wire 110, and the plurality of passive components 130. In FIG. 6, the semiconductor chip 104, the semiconductor chip 108, the bonding wire 110, and the passive components 130 are depicted in dashed lines so that their positional relationship is better understood.

While examples in which the semiconductor chip 104 and the semiconductor chip 108 are respectively connected to the substrate 102 by the bonding wire 106 and the bonding wire 110 have been illustrated in FIGS. 1 to 5, the examples can be arranged to take various forms such as a configuration including a flip-chip interconnection. FIG. 6 illustrates an example in which the semiconductor chip 104 is flip-chip interconnected to the substrate 102.

In addition, also in the present example, the semiconductor chip 104, the semiconductor chip 108, and the plurality of passive components 130 are asymmetrically-positioned with respect to at least line b-b′ that is one center line passing through the center of the substrate 102.

Furthermore, in the present example, in addition to the first resin region 120 and the second resin region 122, the sealing resin 118 includes a third resin region 124 made up of a third resin composition.

In this case, the third resin composition making up the third resin region 124 can also include, as raw materials, a base resin, a hardening agent, and a filler. In addition, the third resin composition can further include, as raw materials, a plasticizer, a hardening accelerator, a latent catalyst, a mold release agent, silicone oil, a stress reducer, a colorant, and the like. Furthermore, the third resin composition making up the third resin region 124 can be arranged so as to differ from the first resin composition and the second resin composition in, for example, fluidity when heated during sealing prior to hardening. Moreover, the third resin composition making up the third resin region 124 can be arranged so as to have, for example, a different hardening/contraction characteristic from the first resin composition and the second resin composition. In addition, the third resin composition making up the third resin region 124 can be arranged so as to have, for example, a different glass-transition temperature (Tg) from the first resin composition and the second resin composition.

In the example illustrated in FIG. 6, the mixed layer 121 is formed over the entire region between the first resin region 120 and the second resin region 122. In addition, a mixed layer 123 that is a mixture of the second resin composition and the third resin composition is formed over the entire region between the second resin region 122 and the third resin region 124. The interface of the second resin region 122 with the mixed layer 123 and the interface of the third resin region 124 with the mixed layer 123 are configured so as to have undulations.

The third resin region 124 does not include bonding wires. In this case, a low-fluidity resin composition can be used as the resin composition that makes up the third resin region 124. Consequently, warpage of the semiconductor device 100 can be reduced.

Furthermore, a highly reliable package can be realized by appropriately optimizing the proportions of the first resin region 120, the second resin region 122, and the third resin region 124. Moreover, by using three or more types of resin compositions as described above, warpage or the like of a package can be suppressed even when the positions of electronic components are irregular and complicated.

Next, a method of manufacturing the semiconductor device 100 according to the present embodiment will be described.

In the present embodiment, sealing using the sealing resin 118 is performed for each semiconductor device 100 corresponding to a single semiconductor chip. In the present embodiment, the semiconductor device 100 is to be sealed using two or more types of resin compositions in a single series of operations. For example, the resin compositions are to be separately prepared for top (resin A) and bottom (resin B) so as to enable resin tablets (cylindrical masses of resin) to be injected in two stages. By placing the resin tablets in a sealing process resin injection slot and sealing the resin tablets, the semiconductor device 100 as described above can be obtained. As shown, since two or more types of resin compositions can be simultaneously hardened, a configuration can be realized in which a mixed layer of the respective resin compositions is formed on an interface of resin regions made up of the respective resin compositions. Due to such a configuration, a favorable adhesion between resins of different types can be achieved.

In the present embodiment, the sealing resin 118 of the semiconductor device 100 can be formed by, for example, a compression molding process, a transfer molding process, a potting process, or a printing process. As an example, a procedure of forming the semiconductor device 100 through a transfer molding process will be described below.

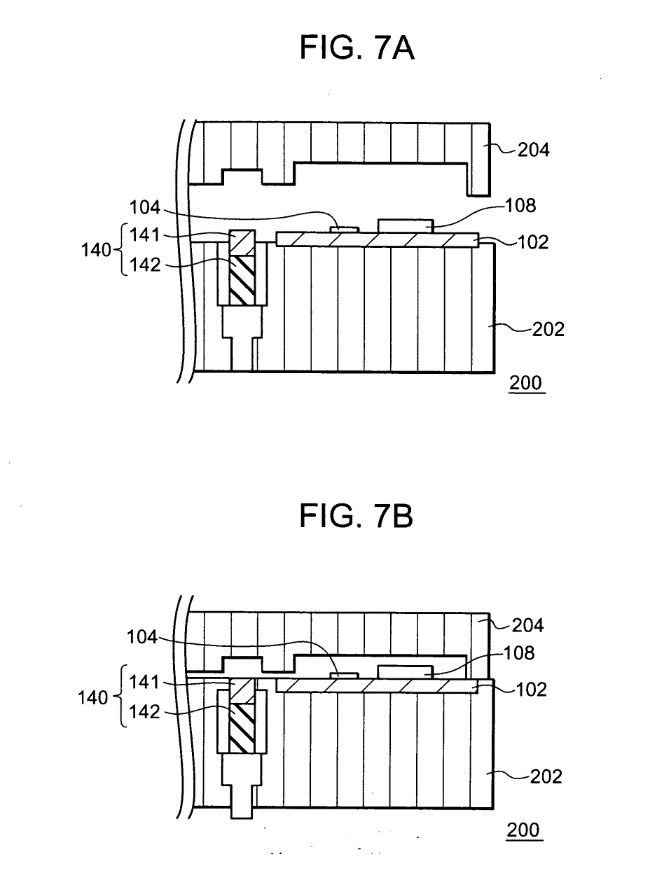

FIG. 7 is a cross-sectional view illustrating a procedure of manufacturing the semiconductor device 100 using a transfer-molding die 200. The die 200 includes a lower die 202 and an upper die 204.

The lower die 202 is provided with a recess for mounting the substrate 102. In addition, the upper die 204 is provided with a recess that forms a cavity for molding the sealing resin 118 between the lower die 202. The lower die 202 is also provided with a slot for injecting sealing resin tablets.

First, the substrate 102 mounted with electronic components such as the semiconductor chip 104 and the semiconductor chip 108 is placed in the recess of the lower die 202. A sealing resin tablet 140 is then set into the slot of the lower die 202 (FIG. 7A).

The tablet can be formed using a resin composition prior to hardening such as granular resin or granular resin formed into a nodule. In the present embodiment, the sealing resin tablet 140 includes the first resin composition 141 that makes up the first resin region 120 and the second resin composition 142 that makes up the second resin region 122. The tablet 140 can also be configured so that individually-formed tablets of the first resin composition 141 and the second resin composition 142 are stacked on top of each other, or be configured by laminating the first resin composition 141 and the second resin composition 142 to form a single tablet. The present embodiment is arranged such that the first resin composition 141 that makes up the first resin region 120 is positioned upwards as seen in the diagram to ensure that the first resin composition 141 is first introduced into the cavity.

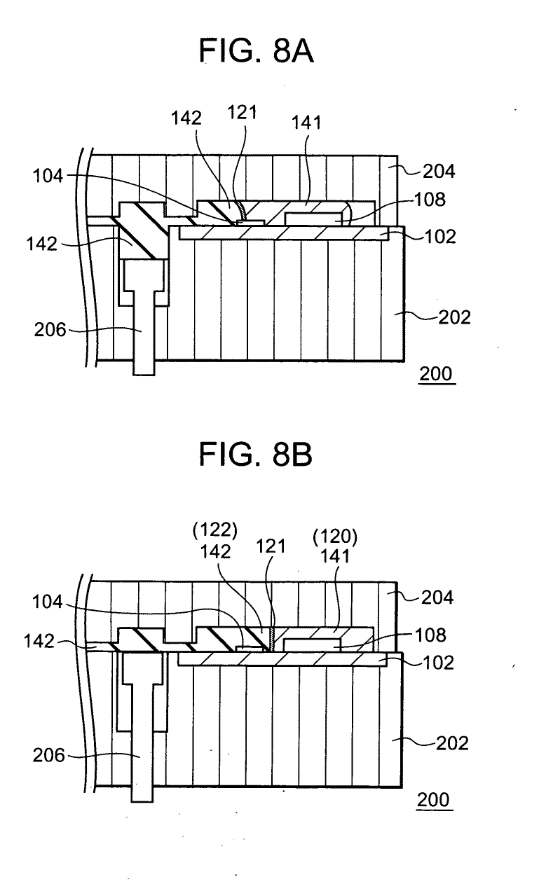

Next, the upper die 204 is moved towards the lower die 202 to form a cavity to mold the sealing resin 118 on the upper face of the substrate 102 (FIG. 7B). Subsequently, the tablet 140 is heated while being pushed by a pushing member 206 to melt the resin composition (FIG. 8A). At this point, the first resin composition 141 positioned on the top of the tablet 140 is introduced into the cavity first. In addition, the second resin composition 142 to be introduced into the cavity afterwards is introduced before the first resin composition 141 introduced earlier hardens, and the two resin compositions are formed in one hardening process.

Accordingly, the sealing resin 118 including the first resin region 120, the mixed layer 121, and the second resin region 122 can be molded (FIG. 8B). In addition, the interface between the first resin region 120 and the mixed layer 121 and the interface between the second resin region 122 and the mixed layer 121 are arranged so as to have undulations.

While an example has been described above in which the resin compositions are tablets, the resin compositions can take any form. However, the resin compositions can be given forms in which shapes are retained to a certain degree so as to prevent a plurality of resin compositions from becoming mixed up during hardening. For example, the resin compositions can be obtained by mixing and kneading raw materials of the resin compositions into a clay form, cooling and crushing the clay-like resin into granular resin, which is then placed in a prescribed container and heated at a low temperature to form (to be semi-hardened to) cylindrical resin (tablets) or flat plate-like resin (preformed resin). In addition, while a procedure has been described above in which sealing is performed for each semiconductor device 100 corresponding to a single semiconductor chip, sealing may alternatively be performed collectively for each wafer corresponding to a plurality of semiconductor chips.

Next, advantages of the semiconductor device 100 according to the present embodiment will be described.

With the semiconductor device 100 according to the present embodiment, even when the positional balance between the sealing resin and electronic components such as a semiconductor chip and passive components differs from location to location, by using a plurality of resin compositions to provide a region in which, as seen in planar view, the electronic components are positioned so as not to overlap each other, and controlling respective positions in the positional patterns and configurations of the first resin region 120, the second resin region 122, and the like, balance can be corrected to reduce the strain on the package and thus reduce warpage.

In addition, with the semiconductor device 100 according to the present embodiment, electronic components can be sealed using a first resin composition and a second resin composition selected depending on the intended use, and at the same time, favorable adhesion can be attained between the first resin region 120 and the second resin region 122 to prevent separation between the two resin regions. Accordingly, an device with high mass-productivity and reliability can be obtained. In addition, favorable characteristics of the device including sealing resin with respect to warpage behavior and the like can be attained. Furthermore, by changing the component ratio of the first resin composition and the second resin composition, warpage behavior can be controlled. Therefore, a highly-reliable package structure with low warpage during sealing and low package warpage can be obtained without having to prepare and/or develop a large number of resin compositions to attain optimum characteristics as was conventional.

For example, in the technique described in Japanese Patent Laid-Open No. 08-162573, a resin hardened body inner layer and a resin hardened body outer layer are respectively formed by transfer molding. As a result, a boundary line is formed between the resin hardened body inner layer and the resin hardened body outer layer. In addition, the presence of mold release agents and oil components on the surface of the resin hardened body inner layer inhibits inter-layer adhesion and problematically causes layer separation, resulting in inferior quality. However, the semiconductor device 100 according to the present embodiment is also capable of solving such problems.

While an embodiment of the present invention has been described above with reference to the drawings, the embodiment merely exemplifies the present invention and various configurations other than those presented above can be adopted.

While examples in which a plurality of electronic components is positioned on the substrate 102 have been presented in the embodiment described above, the configuration of the semiconductor device 100 can also be applied to a case where a single electronic component is positioned on the substrate 102. For example, in a case where a single electronic component is positioned on the substrate 102 and the electronic component is asymmetrically-positioned, as seen in planar view, with respect to at least one center line passing through the center of the substrate 102, there is a problem in that the positional balance between sealing resin and the electronic component differs from location to location, resulting in a difference in the contraction force (internal force) of the sealing resin and creating a strain in the package. Even in such a case, by using a plurality of resin compositions to provide a region in which, as seen in planar view, the electronic components are positioned so as not to overlap each other, balance can be corrected to reduce the strain on the package and reduce warpage.

In addition, various combinations are conceivable with respect to the configurations and positions of the plurality of electronic components and the positions of the plurality of resin compositions. For example, a semiconductor chip and a passive component can be placed on the substrate 102 so as not to overlap each other as seen in planar view, whereby the semiconductor chip is positioned in a region in which only the first resin region 120 exists while the passive component is positioned in a region in which only the second resin region 122 exists.

In this case, for example, a high-fluidity resin composition can be used as the resin composition that makes up the first resin region 120, while a low-fluidity resin composition can be used as the resin composition that makes up the second resin region 122.

Furthermore, the die 200 described with reference to FIG. 7 and FIG. 8 can be configured in various ways. For example, a slot into which sealing resin tablets are to be injected can be provided near a boundary line between two types of resin compositions. In addition, the die 200 can be provided with two or more slots, whereby each resin composition is to be injected into a different slot.

What is claimed is:

1. An electronic device, comprising:
a substrate;
an electronic component mounted on one face of the substrate; and
a sealing resin formed on the one face of the substrate and which seals the electronic component;
wherein the sealing resin includes
a first resin region made up of a first resin composition and
a second resin region made up of a second resin composition,
the sealing resin formed so as to have a region in which only the first resin region exists and a region in which only the second resin region exists, in plan view.

2. The electronic device according to claim 1, wherein
the sealing resin further includes a mixed layer formed between the first resin region and the second resin region and in which the first resin composition and the second resin composition are mixed.

3. The electronic device according to claim 2, wherein
an interface between the first resin region and the mixed layer and an interface between the second resin region and the mixed layer include undulations.

4. The electronic device according to claim 1, wherein
the electronic device is asymmetrically-positioned with respect to at least one center line passing through the center of the substrate, in plan view.

5. The electronic device according to claim 1, comprising
a plurality of the electronic components mounted on the one face of the substrate, wherein the plurality of electronic components is asymmetrically-positioned with respect to at least one center line passing through the center of the substrate, in plan view.

6. The electronic device according to claim 5, wherein
the plurality of electronic components include a semiconductor chip and a passive component which do not overlap each other, in plan view, the semiconductor chip positioned in a region in which only the first resin region exists, and the passive component positioned in a region in which only the second resin region exists.

7. The electronic device according to claim 1, wherein
the first resin composition and the second resin composition differ from each other in the content (percentage by weight) of filler with respect to the entire resin composition.

8. The electronic device according to claim 1, wherein
the first resin composition and the second resin composition differ from each other in types or ratio of raw materials.

9. The electronic device according to claim 1, wherein
the first resin composition and the second resin composition differ from each other in fluidity during sealing.

10. The electronic device according to claim 1, wherein
the sealing resin further includes a third resin region made up of a third resin composition, the sealing resin formed so as to include a region in which only the third resin region exists, in plan view.
